(19) United States
(12) Patent Application Publication
(10) Pub. No.: US 2004/0081757 A1
(43) Pub. Date: Apr. 29, 2004

(54) Substrate treatment device, substrate treatment method, and cleaning method for substrate treatment device

(75) Inventors: Tadahiro Ishizaka, Nirasaki-shi (JP); Kohei Kawamura, Nirasaki-shi (JP); Hiroaki Yokoi, Nirasaki-shi (JP); Takaya Shimizu, Nirasaki-shi (JP); Takashi Shigeoka, Nirasaki-shi (JP); Yasuhiro Oshima, Nirasaki-shi (JP); Yasuhiko Kojima, Nirasaki-shi (JP)

Correspondence Address: PILLSBURY WINTHROP, LLP, P.O. BOX 10500, MCLEAN, VA, 22102, US

(73) Assignee: Tokyo Electron Limited

(21) Appl. No.: 10/650,087

(22) Filed: Aug. 28, 2003

(30) Foreign Application Priority Data
Aug. 30, 2002 (JP) 2002-252273

(51) Int. Cl. C23C 16/00

(52) U.S. Cl. 427/248.1

(57) ABSTRACT

A substrate treatment device includes: a treatment chamber in which a substrate is to be placed; a supply system configured to supply at least two kinds of treatment gases into the treatment chamber; an exhaust system having a pump, configured to exhaust the treatment gases from the treatment chamber; and a capturing unit interposed between the treatment chamber and the pump and containing fine grains, configured to capture by the fine grains at least one kind of the treatment gas exhausted from the treatment chamber.

### CROSS-REFERENCE TO THE INVENTION

This application is based upon and claims the benefit of priority from the prior Japanese Patent Application No. 2002-252273, filed on Aug. 30, 2002; the entire contents of which are incorporated herein by reference.

### BACKGROUND OF THE INVENTION

1. Field of the Invention

The present invention relates to a substrate treatment device that treats a substrate, a substrate treatment method, and a cleaning method for the substrate treatment device.

2. Description of the Related Art

In recent years, there have been demands for higher speed and increasing density in manufacturing semiconductor devices. Accordingly, the hole diameter is becoming remarkably smaller, resulting in a higher aspect ratio.

However, the increase in the aspect ratio tends to lower step coverage of a thin film such as a TiN film and a TiSiN film formed in holes. Such being the case, with the aim of forming thin films excellent in step coverage, a deposition device that forms films while supplying treatment gases alternately has been presently drawing attention.

In forming the TiN film through the use of TiCl₄ and NH₃ by such a deposition device, however, even when a trap is installed, a large amount of yellow powder adheres to an inner wall of an exhaust pipe that is on a downstream side of the trap, concretely, the inner wall of the exhaust pipe whose inner pressure is maintained at an atmospheric pressure. Incidentally, this trap is intended for capturing NH₄Cl that is a byproduct of the reaction. When a TiSiN film is formed through the use of TiCl₄, NH₃, and SiH₂Cl₂, white powder in addition to the yellow power adheres to the inner wall of the exhaust pipe. These powders deposit at every repetition of the film formation, which will be a cause of clogging the pipe. Therefore, there is such a problem that frequent maintenance is necessary for removing the powders adhering to the inner wall of the exhaust pipe by opening the exhaust pipe. Incidentally, this problem may possibly occur also in a deposition device that forms films while supplying treatment gases simultaneously.

### BRIEF SUMMARY OF THE INVENTION

It is an object of the present invention to provide a substrate treatment device, a substrate treatment method, and a cleaning method for the substrate treatment device that are capable of reducing the clogging of an exhaust system.

A substrate treatment device according to an aspect of the present invention is characterized in that it includes: a treatment chamber in which a substrate is to be placed; a supply system configured to supply at least two kinds of treatment gases to the treatment chamber; an exhaust system having a pump, configured to exhaust the treatment gases from the treatment chamber; and a capturing unit interposed between the treatment chamber and the pump and containing fine grains, configured to capture by the fine grains at least one kind of the treatment gas exhausted from the treatment chamber. According to this substrate treatment device of the present invention, a large amount of the treatment gas can be captured in the capturing unit. As a result, the clogging of the exhaust system can be reduced.

The fine grains contained in the capturing unit are preferably zeolite. Zeolite may be either synthetic zeolite or natural zeolite. The use of zeolite makes it possible to inhibit the reaction of the treatment gas captured by zeolite with the other treatment gas.

The capturing unit preferably captures the treatment gas that is liquid or solid at room temperature and at atmospheric pressure. Capturing such a treatment gas makes it possible to inhibit liquid or solid generated in the exhaust system.

The treatment gas captured by the capturing unit is preferably at least one of TiF₄, TiCl₄, TiBr₄, TiI₄, Ti[N(C₂H₅CH₃)₂]₄ (TEMAT), Ti[N(CH₃)₂]₄ (TDMAT), Ti[N(C₂H₅)₂]₄ (TDEAT), TaF₅, TaCl₅, TaBr₅, TaI₅, Ta(NC(CH₃)₃)(N(C₂H₅)₂)₃ (TBTDET), Ta(OC₂H₅)₅, Al(CH₃)₃, Zr(O-t(C₄H₉))₄, ZrCl₄, SiH₄, Si₂H₆, SiH₂Cl₂, and SiCl₄. Capturing these treatment gases makes it possible to inhibit the generation of the powder in the exhaust system.

Another substrate treatment device according to the present invention is characterized in that it includes: a treatment chamber in which a substrate is to be placed; a supply system configured to supply at least two kinds of treatment gases to the treatment chamber; an exhaust system having a pump, configured to exhaust the treatment gases from the treatment chamber; and a capturing unit interposed between the treatment chamber and the pump, configured to capture by a chemical action at least one kind of the treatment gas exhausted from the treatment chamber. The “chemical action” is accompanied by chemical reaction. The “chemical action” includes chemisorption. According to this substrate treatment device of the present invention, a large amount of the treatment gas can be captured in the capturing unit. As a result, the clogging of the exhaust system can be reduced.

The capturing unit preferably has a metal oxide to capture the treatment gas. The use of the metal oxide enables reliable capturing of the treatment gas. The metal oxide is preferably Al₂O₃. The use of Al₂O₃ makes it possible to capture a large amount of the treatment gas even at reduced pressure.

Still another substrate treatment device of the present invention is characterized in that it includes: a treatment chamber in which a substrate is to be placed; a supply system configured to supply at least two kinds of treatment gases to the treatment chamber; an exhaust system having at least one pump, configured to exhaust the treatment gases from the treatment chamber; and an inert gas supply system configured to supply an inert gas into the exhaust system that is on a downstream side of the pump on a final stage. The inert gas is a gas inactive to the treatment gases. According to this substrate treatment device of the present invention, the liquefaction of the treatment gases can be inhibited. As a result, the clogging of the exhaust system can be reduced.

The inert gas preferably includes at least one of Ar, He, and N₂. The use of these gases enables reliable inhibition of the liquefaction of the treatment gas.

Yet another substrate treatment device of the present invention is characterized in that it includes: a treatment chamber in which a substrate is to be placed; a supply system configured to supply at least two kinds of treatment gases into the treatment chamber; an exhaust system having at least one pump, configured to exhaust the treatment gases from the treatment chamber; a heater configured to heat the exhaust system that is on a downstream side of the pump on a final stage. According to this substrate treatment device of the present invention, the liquefaction of the treatment gases can be inhibited. As a result, the clogging of the exhaust system can be reduced.

The treatment gases may include at least one of TiF₄, TiCl₄, TiBr₄, TiI₄, Ti[N(C₂H₅CH₃)₂]₄, Ti[N(CH₃)₂)]₄, Ti[N(C₂H₅)₂]₄, TaF₅, TaCl₅, TaBr₅, TaI₅, Ta(NC(CH₃)₃)(N(C₂H₅)₂)₃, Ta(OC₂H₅)₅, Al(CH₃)₃, Zr(O-t(C₄H⁹))₄, ZrCl₄, SiH₄, Si₂H₆, SiH₂Cl₂, and SiCl₄. These gases are gases that may possibly cause the clogging of the exhaust system, but according to this substrate treatment device of the present invention, the clogging of the exhaust system can be reduced, which allows the use of these gases.

The substrate treatment device preferably further includes a supply controller configured to control the supply system to supply the treatment gases alternately. When the supply controller is provided, a high-quality film can be formed.

A substrate treatment method according to another aspect of the present invention includes: a metal-containing gas supply step of supplying a metal-containing gas at a first flow rate into a treatment chamber while the treatment chamber has a substrate placed therein; a metal-containing gas exhaust step of exhausting the metal-containing gas from the treatment chamber via an exhaust system; a nitriding agent gas supply step of supplying a nitriding agent gas into the treatment chamber at a second flow rate that is 10 times as large as the first flow rate or at a larger rate; and a nitriding agent exhaust step of exhausting the nitriding agent gas from the treatment chamber via the exhaust system. The metal-containing gas exhaust step may be conducted either after the metal-containing gas supply step or during the metal-containing gas supply step. The nitriding agent gas supply step may be conducted either after the metal-containing gas supply step or during the metal-containing gas supply step. The nitriding agent gas exhaust step may be conducted either after the nitriding agent gas supply step or during the nitriding agent gas supply step. According to this substrate treatment method of the present invention, the clogging of the exhaust system can be reduced.

The nitriding agent gas is preferably supplied at a flow rate of 300 sccm to 1000 sccm. The supply of the nitriding agent gas at such a flow rate makes it possible to reduce the clogging of the exhaust system reliably.

The metal-containing gas may include at least one of TiF₄, TiCl₄, TiBr₄, TiI₄, Ti[N(C₂H₅CH₃)₂]₄, Ti[N(CH₃)₂]₄, Ti[N(C₂H₅)₂]₄, TaF₅, TaCl5, TaBr₅, TaI₅, and Ta(NC(CH₃)₃)(N(C₂H₅)₂)₃. These gases are gases that may possibly cause the clogging of the exhaust system, but according to this substrate treatment method of the present invention, the clogging of the exhaust system can be reduced, which allows the use of these gases.

The nitriding agent gas preferably includes NH₃. When it includes NH₃, the clogging of the exhaust system can be more reliably reduced.

A cleaning method for a substrate treatment device according to still another aspect of the present invention is characterized in that it includes: a substrate treatment device preparing step of preparing a substrate treatment device that treats a substrate by supplying a metal-containing gas and a nitriding agent gas to the substrate; and a nitriding agent gas supply step of supplying a nitriding agent gas into an exhaust system of the substrate treatment device while the substrate treatment device does not have the substrate placed therein. According to this cleaning method for the substrate treatment device of the present invention, the clogging of the exhaust system can be reduced.

The nitriding agent gas supplied in the nitriding agent gas supply step is preferably supplied at a flow rate larger than a flow rate of the nitriding agent gas supplied for the treatment. The supply of the nitriding agent gas at such a flow rate makes it possible to reduce the clogging of the exhaust system reliably.

The nitriding agent gas supplied in the nitriding agent gas supply step is preferably supplied at a flow rate of 300 sccm to 1000 sccm. The supply of the nitriding agent gas at such a flow rate makes it possible to more reliably reduce the clogging of the exhaust system.

The metal-containing gas may include at least one of TiF₄, TiCl₄, TiBr₄, TiI₄, Ti[N(C2H₅CH₃)₂]₄, Ti[N(CH₃)₂]₄, Ti[N(C₂H₅)₂]₄, TaF₅, TaCl₅, TaBr₅, TaI₅ and Ta(NC(CH₃)₃)(N(C₂H₅)₂)₃. These gases are gases that may possibly cause the clogging of the exhaust system, but according to this cleaning method for the substrate treatment device of the present invention, the clogging of the exhaust system can be reduced, which allows the use of these gases.

The nitriding agent gas preferably includes NH₃. When it includes NH₃, the clogging of the exhaust system can be more reliably reduced.

Another cleaning method of a substrate treatment device of the present invention is characterized in that it includes a nitriding agent gas supply step of supplying a nitriding agent gas into an exhaust system of the substrate treatment device that treats a substrate by supplying a metal-containing gas and a nitriding agent gas, while the substrate treatment device does not have the substrate placed therein. According to this cleaning method of the present invention, the clogging of the exhaust system can be reduced.

### BRIEF DESCRIPTION OF THE DRAWINGS

FIG. 1 is a schematic block diagram showing a deposition device according to a first embodiment.

FIG. 2 is a schematic vertical sectional view of a capturing unit according to the first embodiment.

FIG. 3 is a flowchart showing the flow of the treatment conducted in the deposition device according to the first embodiment.

FIG. 4A to FIG. 4D are views schematically showing the treatment conducted in the deposition device according to the first embodiment.

FIG. 5 is a schematic block diagram of a deposition device according to a second embodiment.

FIG. 6 is a schematic vertical sectional view of a capturing unit according to the second embodiment.

FIG. 7 is a flow chart showing the flow of the treatment conducted in the deposition device according to the second embodiment.

FIG. 8A and FIG. 8B are views schematically showing the treatment conducted in the deposition device according to the second embodiment.

FIG. 9 is a schematic block diagram of a deposition device according to a third embodiment.

FIG. 10 is a flowchart showing the flow of the treatment conducted in the deposition device according to the third embodiment.

FIG. 11 is a view schematically showing the treatment conducted in the deposition device according to the third embodiment.

FIG. 12 is a schematic block diagram of a deposition device according to a fourth embodiment.

FIG. 13 is a flowchart showing the flow of the treatment conducted in the deposition device according to the fourth embodiment.

FIG. 14 is a view schematically showing the treatment conducted in the deposition device according to the fourth embodiment.

FIG. 15 is a flowchart showing the flow of the treatment conducted in a deposition device according to a fifth embodiment.

FIG. 16 is a flowchart showing the flow of the overall treatment conducted in a deposition device according to a sixth embodiment.

FIG. 17 is a flowchart showing the flow of the treatment for one piece of wafer conducted in the deposition device according to the sixth embodiment.

FIG. 18 is a view schematically showing the treatment conducted in the deposition device according to the sixth embodiment.

### DETAILED DESCRIPTION OF THE INVENTION

(First Embodiment)

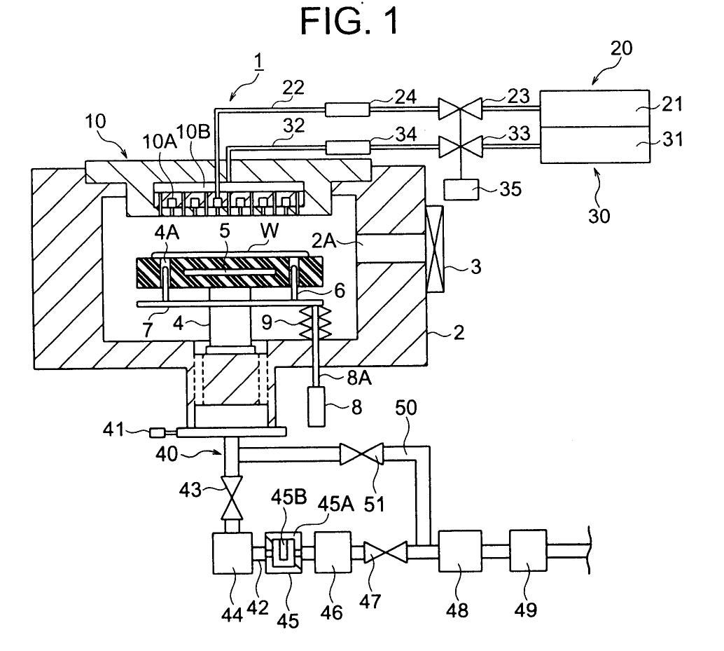

Hereinafter, a deposition device according to a first embodiment of the present invention will be explained. FIG. 1 is a schematic block diagram of the deposition device according to this embodiment.

As shown in FIG. 1, a deposition device 1 has a chamber 2 formed of, for example, aluminum or stainless steel. Incidentally, surface treatment, for example, the treatment of anodized aluminum may be applied to the surface of the chamber 2. The chamber 2 has an opening 2A formed in a side portion thereof, and near the opening 2A, a gate valve 3 intended for allowing a semiconductor wafer (hereinafter, simply referred to as a ‘wafer’) W to be carried into or carried out of the chamber 2 is attached.

A susceptor 4 in a substantially disc shape to place the wafer W thereon is disposed in the chamber 2. The susceptor 4 is formed of, for example, ceramics such as AlN or Al₂O₃. A heater 5 for heating the susceptor 4 to a predetermined temperature is provided in the susceptor 4. When the heater 5 heats the susceptor 4 to the predetermined temperature, the wafer W placed on the susceptor 4 is heated to the predetermined temperature.

Holes 4A intended for a wafer up/down are formed in a vertical direction at three places of the susceptor 4. Wafer up/down pins 6 insertable into the holes 4A are provided at lower portions of the holes 4A respectively. The wafer up/down pins 6 are fixed onto a wafer up/down pin support table 7 so as to vertically stand. An air cylinder 8 is fixed to the wafer up/down pin support table 7. When a rod 8A of the air cylinder 8 is contracted by the drive of the air cylinder 8, the wafer up/down pins 6 are moved down so that the wafer W is placed on the susceptor 4. When the rod 8A is extended by the drive of the air cylinder 8, the wafer up/down pins 6 are moved up so that the wafer W is detached from the susceptor 4. A contractible/extendable bellows 9 covering the rod 8A is disposed in the chamber 2. By covering the rod 8A with the bellows 9, airtightness inside the chamber 2 is maintained.

An opening is formed in an upper portion of the chamber 2. A showerhead 10 to introduce TiCl₄ and NH₃ to the susceptor 4 is inserted in the opening. The showerhead 10 is divided into a TiCl₄ introducing portion 10A and an NH₃ introducing portion 10B. A large number of TiCl₄ introducing ports through which TiCl₄ is supplied are formed in the TiCl₄ introducing portion 10A. Similarly, a large number of NH₃ introducing ports through which NH₃ is supplied are formed in the NH₃ introducing portion 10B.

A TiCl₄ supply system 20 to supply TiCl₄ to the TiCl₄ introducing portion 10A is connected to the TiCl₄ introducing portion 10A of the showerhead 10. An NH₃ supply system 30 to supply NH₃ to the NH₃ introducing portion 10B is connected to the NH₃ introducing portion 10B.

The TiCl₄ supply system 20 has a TiCl₄ supply source 21 storing TiCl₄ therein. A TiCl₄ supply pipe 22 having one end connected to the TiCl₄ introducing portion 10A is connected to the TiCl₄ supply source 21. A valve 23 and a mass flow controller (MFC) 24 to control the flow rate of TiCl₄ are disposed in the TiCl₄ supply pipe 22. When the valve 23 is opened while the mass flow controller 24 is in a controlled state, TiCl₄ is supplied to the TiCl₄ introducing portion 10A from the TiCl₄ supply source 21 at a predetermined flow rate.

The NH₃ supply system 30 has an NH₃ supply source 31 storing NH₃ therein. An NH₃ supply pipe 32 having one end connected to the NH₃ introducing portion 10B is connected to the NH₃ supply source 31. A valve 33 and a mass flow controller 34 to control the flow rate of NH₃ are disposed in the NH₃ supply pipe 32. When the valve 33 is opened while the mass flow controller 34 is in a controlled state, NH₃ is supplied to the showerhead 10 from the NH₃ supply source 31 at a predetermined flow rate.

A valve controller 35 that controls the valves 23, 33 so as to alternately open the valve 23, 33 is electrically connected to the valves 23, 33. Owing to such control over the valves 23, 33 by the valve controller 35, a TiN film excellent in step coverage is formed on the wafer W.

An exhaust system 40 to exhaust gases such as TiCl₄ and NH₃ is connected to a bottom portion of the chamber 2. The exhaust system 40 has an auto-pressure controller (APC) 41 to control the pressure inside the chamber 2. When conductance is adjusted by the auto-pressure controller 41, the pressure inside the chamber 2 is controlled at a predetermined pressure.

An exhaust pipe 42 is connected to the auto-pressure controller 41. The other end of the exhaust pipe 42 is open to the atmosphere. In the exhaust pipe 42, a main valve 43, a turbo molecular pump 44, a trap 45, a capturing unit 46, a valve 47, a dry pump 48, and a capturing unit 49 are arranged in this order from an upstream side to a downstream side.

The turbo molecular pump 44 conducts high evacuation. The high evacuation by the turbo molecular pump 44 causes the pressure inside the chamber 2 to be maintained at a predetermined pressure. The turbo molecular pump 44 is also intended for exhausting excessive TiCl₄, NH₃, TiN, NH₄Cl, and so on from the chamber 2.

The trap 45 is intended for capturing NH₄Cl contained in an exhaust gas to remove NH₄Cl from the exhaust gas. The trap 45 has a housing 45A in which a flow-in port for letting the exhaust gas in therethrough and a flow-out port for letting the exhaust gas out therethrough are formed. A plate member 45B is disposed in the housing 45A, and the plate member 45B is cooled by a not-shown cooler. When powder of NH₄Cl comes into contact with the cooled plate member 45B, the plate member 45B adsorbs the powder of NH₄Cl by physical adsorption, so that NH₄Cl is removed from the exhaust gas.

The dry pump 48 is intended for assisting the turbo molecular pump 44. The dry pump 48 also conducts low evacuation of the inside of the chamber 2. When the pressure of a subsequent stage of the turbo molecular pump 44 is reduced by the dry pump 48, the exhaust rate of the turbo molecular pump 44 can be increased.

A roughing out pipe 50 for use in low evacuation by the dry pump 48 is connected to the exhaust pipe 42 between the valve 47 and the dry pump 48. The other end of the roughing out pipe 50 is connected to the exhaust pipe 42 between the auto-pressure controller 41 and the main valve 43. A valve 51 is disposed in the roughing out pipe 50.

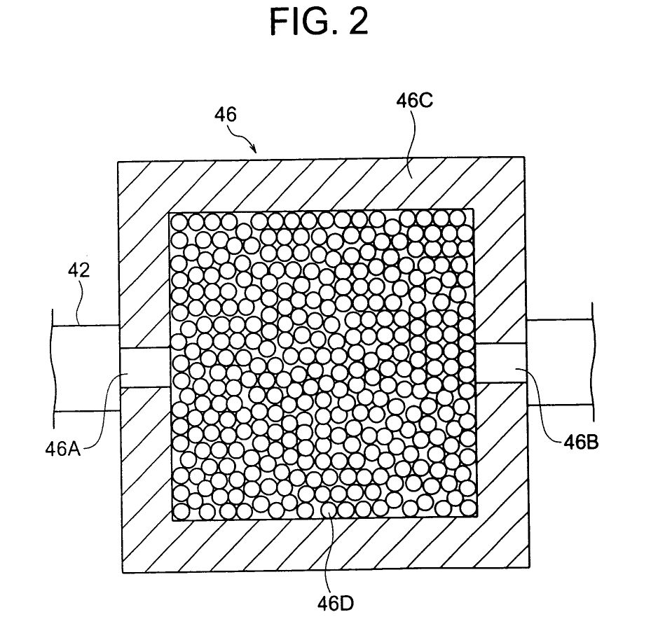

The capturing units 46, 49 are intended for capturing TiCl₄ contained in the exhaust gas to remove TiCl₄ from the exhaust gas. The capturing unit 46 will be explained in detail below. FIG. 2 is a schematic vertical sectional view of the capturing unit 46 according to this embodiment.

As shown in FIG. 2, the capturing unit 46 has a housing 46C in which a flow-in port 46A for letting the exhaust gas in therethrough and a flow-out port 46B for letting the exhaust gas out therethrough are formed. Fine-grained synthetic zeolite 46D is contained in the housing 46C. When TiCl₄ contained in the exhaust gas comes into contact with the synthetic zeolite 46D, the synthetic zeolite 46D adsorbs TiCl₄ by physical adsorption, so that TiCl₄ is removed from the exhaust gas.

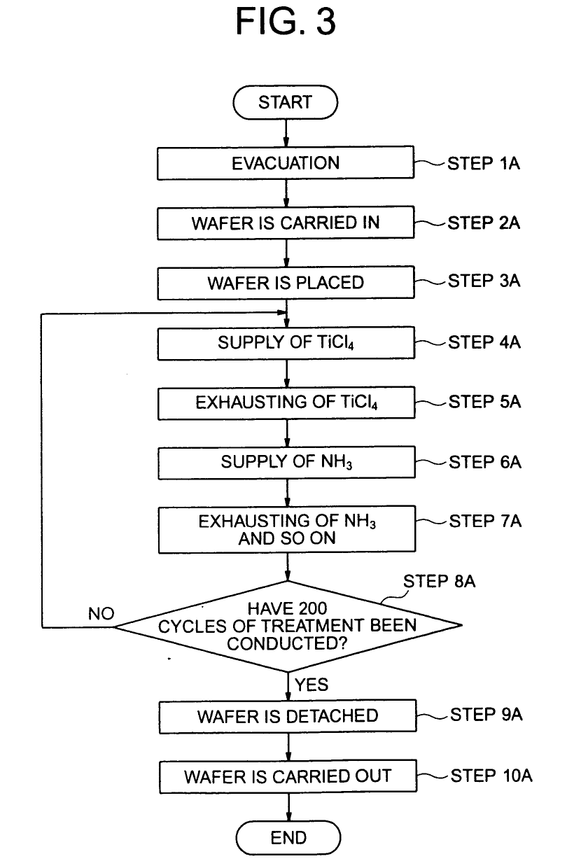

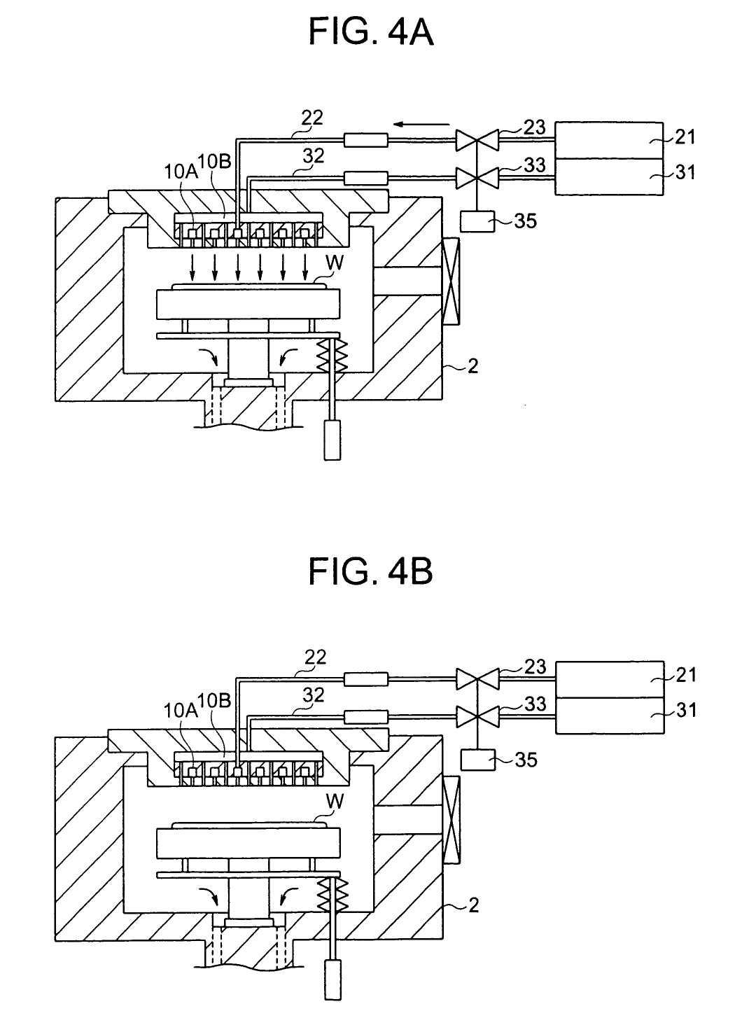

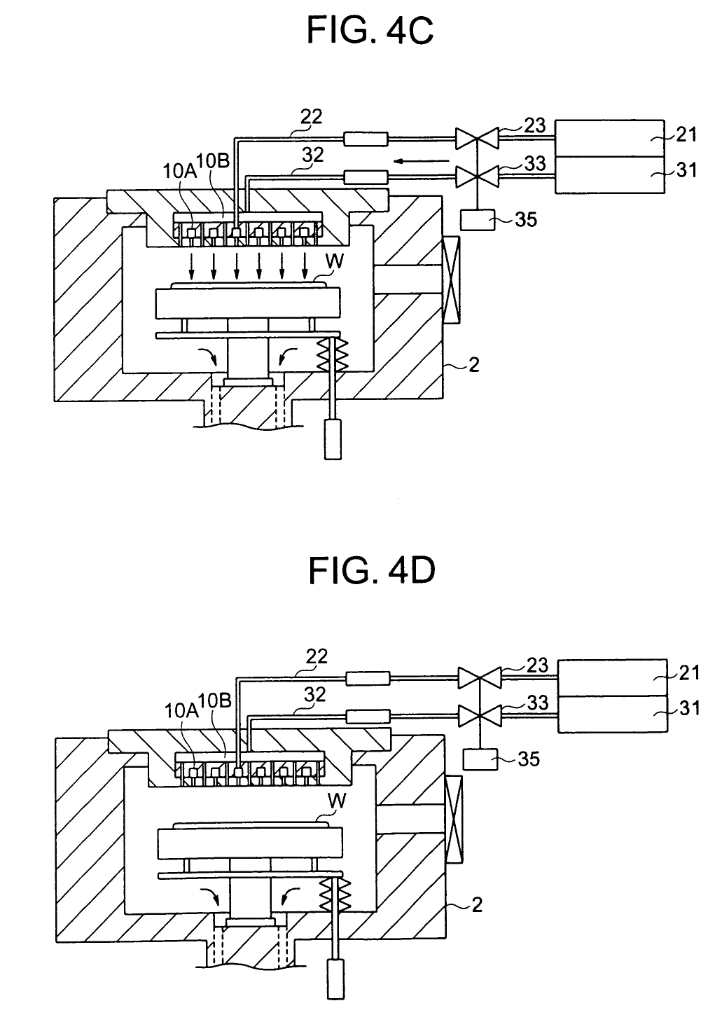

Hereinafter, the flow of the treatment conducted in the deposition device 1 will be explained, following FIG. 3 to FIG. 4D. FIG. 3 is a flowchart showing the flow of the treatment conducted in the deposition device 1 according to this embodiment, and FIG. 4A to FIG. 4D are views schematically showing the treatment conducted in the deposition device 1 according to this embodiment.

First, the main valve 43 and the valve 47 are closed, and while the valve 51 is in an open state, the dry pump 48 operates to conduct low evacuation of the inside of the chamber 2. Thereafter, when the pressure in the chamber 2 is reduced to some extent, the valve 51 is closed and at the same time, the main valve 43 and the valve 47 are opened, so that the low evacuation by the dry pump 48 is changed to the high evacuation by the turbo molecular pump 44 (Step 1A). Note that the dry pump 48 is kept operating even after this change.

After the pressure inside the chamber 2 is reduced to, for example, 1.33×10⁻² Pa or lower, the gate valve 3 is opened and a not-shown transfer arm holding the wafer W extends to carry the wafer W into the chamber 2 (Step 2A).

Thereafter, the transfer arm contracts and the wafer W is placed on the wafer up/down pins 6. After the wafer W is placed on the wafer up/down pins 6, the wafer up/down pins 6 are moved down by the drive of the air cylinder 8, so that the wafer W is placed on the susceptor 4 having been heated to about 300° C. to about 450° C. (Step 3A).

After the temperature of the wafer W is raised, the valve 23 is opened while the pressure inside the chamber 2 is kept at about 50 Pa to about 400 Pa, so that TiCl₄ is introduced to the wafer W from the TiCl₄ introducing portion 10A at a flow rate of about 30 sccm, as shown in FIG. 4A (Step 4A). When the introduced TiCl₄ comes into contact with the wafer W, TiCl₄ is adsorbed over the surface of the wafer W.

After a predetermined period of time passes, the valve 23 is closed to stop the supply of TiCl₄, and at the same time, TiCl₄ remaining in the chamber 2 is exhausted from the chamber 2, as shown in FIG. 4B (Step 5A). Note that the pressure inside the chamber 2 at the time of the exhausting becomes 6.67×10⁻² Pa or lower.

After a predetermined period of time passes, the valve 33 is opened, so that NH₃ is introduced to the wafer W from the NH₃ j introducing portion 10B at a flow rate of about 100 sccm, as shown in FIG. 4C (Step 6A). When the introduced NH₃ comes into contact with TiCl₄ adsorbed by the wafer W, TiCl₄ and NH₃ react with each other, so that a TiN film is formed on the wafer W.

After a predetermined period of time passes, the valve 33 is closed to stop the supply of NH₃, and at the same time, NH₃ and so on remaining in the chamber 2 are exhausted from the chamber 2, as shown in FIG. 4D (Step 7A). Note that the pressure inside the chamber 2 at the time of the exhausting becomes 6.67×10⁻² Pa or lower.

After a predetermined period of time passes, it is judged by a not-shown central controller whether or not 200 cycles of the treatment have been conducted, with the processes from Step 4A to Step 7A being one cycle (Step 8A). When it is judged that 200 cycles of the treatment have not been conducted, the processes from Step 4A to Step 7A are conducted again.

When it is judged that 200 cycles of the treatment have been conducted, the wafer up/down pins 6 are moved up by the drive of the air cylinder 8, so that the wafer W is detached from the susceptor 4 (Step 9A). Note that when 200 cycles of the treatment are conducted, the TiN film with a thickness of about 10 nm is formed on the wafer W.

Thereafter, after the gate valve 3 is opened, the not-shown transfer arm extends to hold the wafer W. Finally, the transfer arm contracts to carry the wafer W out of the chamber 2 (Step 10A).

In this embodiment, since the capturing unit 46 containing the fine grains is disposed between the chamber 2 and the dry pump 48, the clogging of the exhaust pipe 42 can be reduced. To be more specific, yellow powder adhering to an inner wall of the exhaust pipe is generated by the reaction between TiCl₄ and NH₃ that are exhausted from the chamber. Concretely, the yellow powder is TiCl₄ n NH₃(n=2, 4), which is generated by the reaction between TiCl₄ and NH₃ at about 150° C. or lower. The possible reason why a large amount of the yellow powder adheres to the inner wall of the exhaust pipe maintained at the atmospheric pressure is that TiCl₄ is liquefied or a large amount of TiCl₄ adheres to the inner wall of the exhaust pipe. Concretely, as for the liquefaction of TiCl₄, when TiCl₄ is liquefied, it is difficult for the liquefied TiCl₄ to move. When NH₃ flows therein, the reaction between TiCl₄ and NH₃ occurs one after another. This is the possible reason for the adhesion of a large amount of the yellow powder to the inner wall of the exhaust pipe maintained at the atmospheric pressure. As for the adhesion of a large amount of TiCl₄ to the inner wall of the exhaust pipe, at the atmospheric pressure, TiCl₄ is more easily adsorbed by the inner wall of the exhaust pipe and the adsorbed TiCl₄ is more difficult to be detached than at the reduced pressure. Therefore, an adhesion amount of TiCl₄ to the inner wall of the exhaust pipe increases. When NH₃ flows therein, the reaction between TiCl₄ and NH₃ occurs one after another. This is the possible reason for the adhesion of a large amount of the yellow powder to the inner wall of the exhaust pipe 42 maintained at the atmospheric pressure. Therefore, when TiCl₄ is captured at the reduced pressure, the generation of the yellow powder is inhibited, so that the adhesion of the yellow powder to the inner wall of the exhaust pipe maintained at the atmospheric pressure is inhibited. Here, a trap provided in a conventional deposition device is installed under the condition of the reduced pressure, and therefore, this trap is also likely to be capable of capturing TiCl₄, but the surface area of the trap is small. Accordingly, an amount of TiCl₄ captured by the trap is very small, which is the possible reason for not allowing effective inhibition of the generation of the yellow powder. In this embodiment, on the other hand, since TiCl₄ is captured by the fine grains, the surface area is large, so that a large amount of TiCl₄ can be captured. Consequently, it is possible to greatly reduce the yellow powder adhering to the inner wall of the exhaust pipe 42, resulting in the reduction in the clogging of the exhaust pipe 42. As a result, maintenance frequency can be lowered.

In this embodiment, owing to the use of the synthetic zeolite 46D, TiCl₄ adsorbed by the synthetic zeolite 46D does not easily react with NH₃ that flows in thereafter. As a result, reliable inhibition of the generation of the yellow powder is realized.

In this embodiment, TiCl₄ and NH₃ are alternately supplied, and even in such a case, the generation of the yellow powder can be reliably inhibited. Specifically, the comparison of the alternate supply of TiCl₄ and NH₃ with the simultaneous supply of TiCl₄ and NH₃ shows that an amount of TiCl₄ exhausted from the chamber 2 is larger in the alternate supply. Therefore, an amount of the generated yellow powder becomes larger in the alternate supply than in the simultaneous supply. In this embodiment, since TiCl₄ can be reliably captured, the generation of the yellow powder can be reliably inhibited even when TiCl₄ and NH₃ are alternately supplied.

(Second Embodiment)

Hereinafter, a second embodiment of the present invention will be explained. Note that some of the contents of this embodiment and embodiments thereafter that are the same as those in the previous embodiment will be omitted in the explanation. In this embodiment, the explanation will be given on an example where a capturing unit contains aluminum oxide (Al₂O₃) in addition to synthetic zeolite.

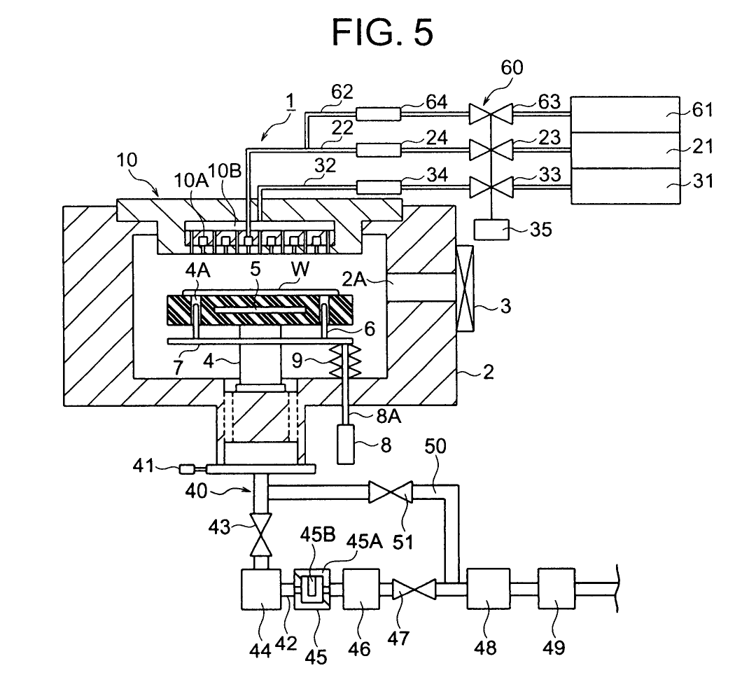

FIG. 5 is a schematic block diagram of a deposition device according to this embodiment. As shown in FIG. 5, a deposition device 1 has an SiH₂Cl₂ supply system 60. The SiH₂Cl₂ supply system 60 has an SiH₂Cl₂ supply source 61 storing SiH₂Cl₂ therein. An SiH₂Cl₂ supply pipe 62 having one end connected to a TiCl₄ supply pipe 22 is connected to the SiH₂Cl₂ supply source 61. A valve 63 and a mass flow controller 64 to control the flow rate of SiH₂Cl₂ are disposed in the SiH₂Cl₂ supply pipe 62. The valve 63 is opened while the valve 23 is in a closed state and the mass flow controller 64 is in a controlled state, so that SiH₂Cl₂ is supplied to a TiCl₄ introducing portion 10A from the SiH₂Cl₂ supply source 61 at a predetermined flow rate.

A valve controller 35 to control the valves 23, 33, 63 so as to open the valve 23, 33, 63 by turns is electrically connected to the valve 63. Owing to such control over the valves 23, 33, 63 by the valve controller 35, a TiSiN film excellent in step coverage is formed on a wafer W.

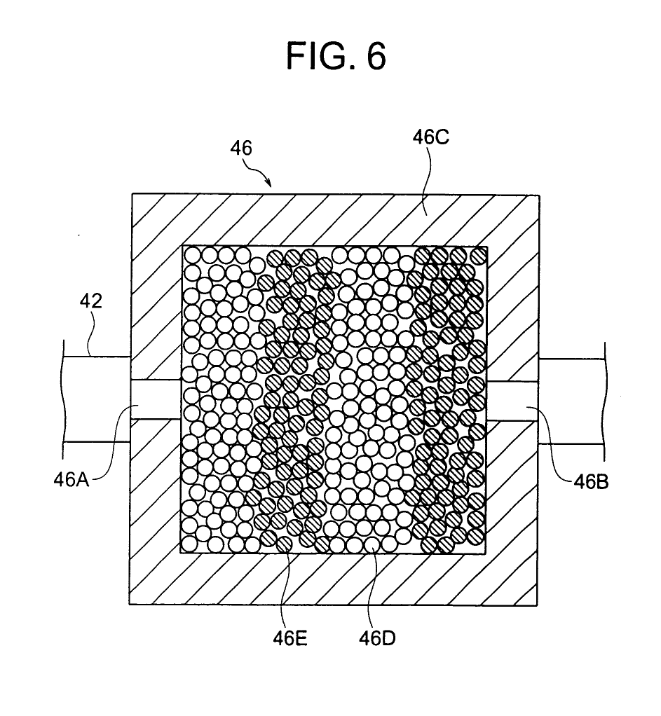

Next, a capturing unit 46 in this embodiment will be explained. FIG. 6 is a schematic vertical sectional view of the capturing unit 46 according to this embodiment. As shown in FIG. 6, fine-grained synthetic zeolite 46D and fine-grained aluminum oxide 46E are put in an alternate layered state in the capturing unit 46. When SiH₂Cl₂ contained in an exhaust gas comes into contact with the aluminum oxide 46E, SiH₂Cl₂ is adsorbed by the aluminum oxide 46E by chemisorption, so that SiH₂Cl₂ is removed from the exhaust gas.

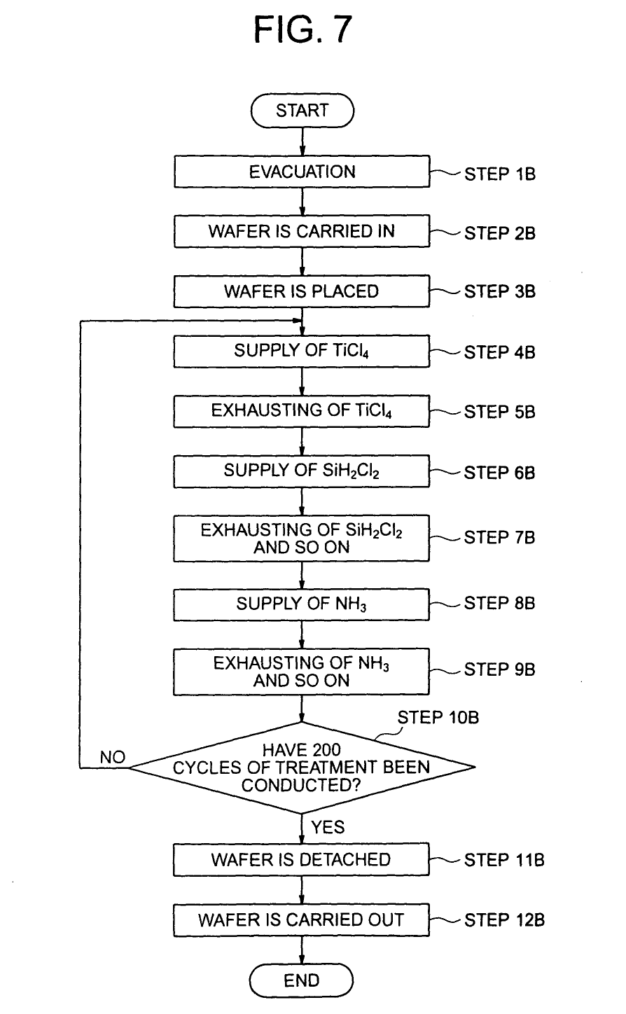

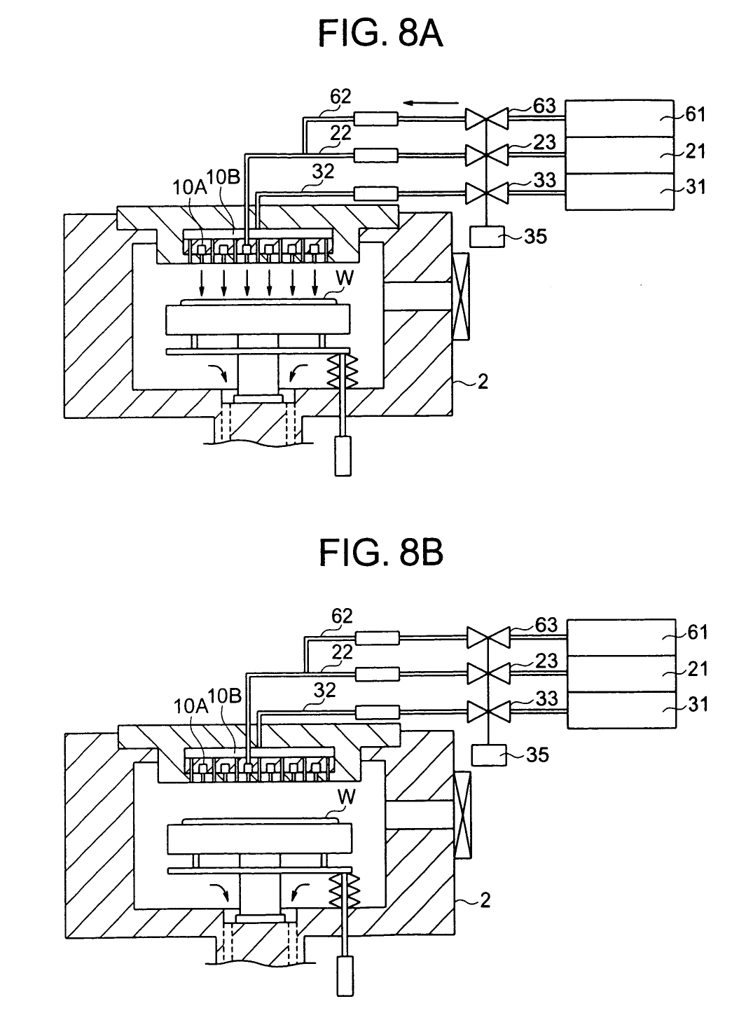

Hereinafter, the flow of the treatment conducted in the deposition device 1 will be explained, following FIG. 7 to FIG. 8B. FIG. 7 is a flowchart showing the flow of the treatment conducted in the deposition device 1 according to this embodiment, and FIG. 8A and FIG. 8B are views schematically showing the treatment conducted in the deposition device 1 according to this embodiment.

A dry pump 48 is operated to conduct low evacuation of the inside of a chamber 2. Thereafter, the low evacuation by the dry pump 48 is changed to high evacuation by a turbo molecular pump 44 (Step 1B).

After the pressure inside the chamber 2 is reduced to, for example, 1.33×10⁻² Pa or lower, a not-shown transfer arm holding the wafer W extends to carry the wafer W into the chamber 2 (Step 2B). Thereafter, wafer up/down pins 6 are moved down to place the wafer W on a susceptor 4 (Step 3B).

After the temperature of the wafer W is raised, the valve 23 is opened while the pressure inside the chamber 2 is kept at about 50 Pa to about 400 Pa, so that TiCl₄ is introduced from the TiCl₄ introducing portion 10A (Step 4B). After a predetermined period of time passes, the valve 23 is closed to stop the supply of TiCl₄ and at the same time, TiCl₄ remaining in the chamber 2 is exhausted from the chamber 2 (Step 5B).

After a predetermined period of time passes, the valve 63 is opened, so that SiH₂Cl₂ is introduced from the TiCl₄ introducing portion 10A at a flow rate of about 30 sccm, as shown in FIG. 8A (Step 6B). When the introduced SiH₂Cl₂ comes into contact with TiCl₄ adsorbed by the wafer W, TiCl₄ and SiH₂Cl₂ react with each other, so that a film in which Ti and Si are bonded together is formed on the wafer W. After a predetermined period of time passes, the valve 61 is closed to stop the supply of SiH₂Cl₂ and at the same time, SiH₂Cl₂ and so on remaining in the chamber 2 are exhausted from the chamber 2, as shown in FIG. 8B (Step 7B).

After a predetermined period of time passes, the valve 33 is opened, so that NH₃ is introduced from an NH₃ introducing portion 10B (Step 8B). When the introduced NH₃ comes into contact with the film in which Ti and Si are bonded together on the wafer W, the film in which Ti and Si are bonded together react with NH₃, so that a TiSiN film is formed on the wafer W. After a predetermined period of time passes, the valve 33 is closed to stop the supply of NH₃, and at the same time, NH₃ and so on remaining in the chamber 2 are exhausted from the chamber 2 (Step 9B).

After a predetermined period of time passes, it is judged whether or not 200 cycles of the treatment, with the processes from Step 4B to Step 9B being one cycle, have been conducted (Step 10B). When it is judged that 200 cycles of the treatment have not been conducted, the processes from Step 4B to Step 9B are conducted again.

When it is judged that 200 cycles of the treatment have been conducted, the wafer up/down pins 6 are moved up, so that the wafer W is detached from the susceptor 4 (Step 11B). Finally, the wafer W is carried out of the chamber 2 by the not-shown transfer arm (Step 12B).

In this embodiment, since the capturing unit 46 containing the aluminum oxide 46E is disposed between the chamber 2 and the dry pump 48, the clogging of an exhaust pipe 42 can be reduced. To be more specific, white powder adhering to an inner wall of the exhaust pipe is generated by the reaction between SiH₂Cl₂ and NH₃ that are exhausted from the chamber. Specifically, the white powder is NH₄Cl. The possible reason why a large amount of the white powder adheres to the inner wall of the exhaust pipe maintained at the atmospheric pressure is that a large amount of SiH₂Cl₂ adheres to the inner wall of the exhaust pipe. Concretely, as described above, at the atmospheric pressure, SiH₂Cl₂ is more easily adsorbed by the inner wall of the exhaust pipe and the adsorbed SiH₂Cl₂ is more difficult to be detached than at the reduced pressure. Therefore, an adhesion amount of SiH₂Cl₂ to the inner wall of the exhaust pipe increases. When NH₃ flows therein, the reaction between SiH₂Cl₂ and NH₃ occurs one after another. This is the possible reason for the adhesion of a large amount of the white powder to an inner wall of the exhaust pipe maintained at the atmospheric pressure. Here, NH₄Cl is also captured in a trap provided in a conventional deposition device, but NH₄Cl that this trap is capable of capturing is mainly NH₄Cl generated in the chamber, and NH₄Cl generated at the atmospheric pressure cannot be captured. This is the possible reason for not allowing effective inhibition of the generation of the white powder. In this embodiment, on the other hand, SiH₂Cl₂ that is a generating source of NH₄Cl is captured in advance at the reduced pressure, so that it is possible to greatly reduce the white powder adhering to the inner wall of the exhaust pipe 42, thereby reducing the clogging of the exhaust pipe 42. As a result, maintenance frequency can be lowered.

In this embodiment, the aluminum oxide 46E captures SiH₂Cl₂ by chemisorption. Here, since chemisorption is the adsorption by chemical reaction, even a gas can be adsorbed reliably. Accordingly, an amount of SiH₂Cl₂ captured in this case is larger than that when SiH₂Cl₂ is captured by physical adsorption.

In this embodiment, since the aluminum oxide 46E is contained in a fine-grained state, so that the surface area thereof is large. Therefore, a larger amount of SiH₂Cl₂ can be captured.

In this embodiment, TiCl₄, SiH₂Cl₂, and NH₃ are supplied by turns, and even in such a case, the generation of the white powder can be reliably inhibited. Specifically, the comparison of the supply of TiCl₄, SiH₂Cl₂, and NH₃ by turns with the simultaneous supply of TiCl₄, SiH₂Cl₂, and NH₃ shows that an amount of SiH₂Cl₂ exhausted from the chamber 2 is larger in the supply by turns. Therefore, an amount of the generated white powder is larger in the supply by turns than in the simultaneous supply. In this embodiment, since SiH₂Cl₂ can be reliably captured, the generation of the white powder can be reliably inhibited even when TiCl₄, SiH₂Cl₂, and NH₃ are supplied by turns. Since the capturing unit 46E also contains the synthetic zeolite 46D, the same effect as in the first embodiment is obtainable.

(Third Embodiment)

Hereinafter, a third embodiment of the present invention will be explained. In this embodiment, the explanation will be given on an example where provided is an N₂ supply system to supply N₂ into an exhaust pipe that is on a downstream side of a dry pump.

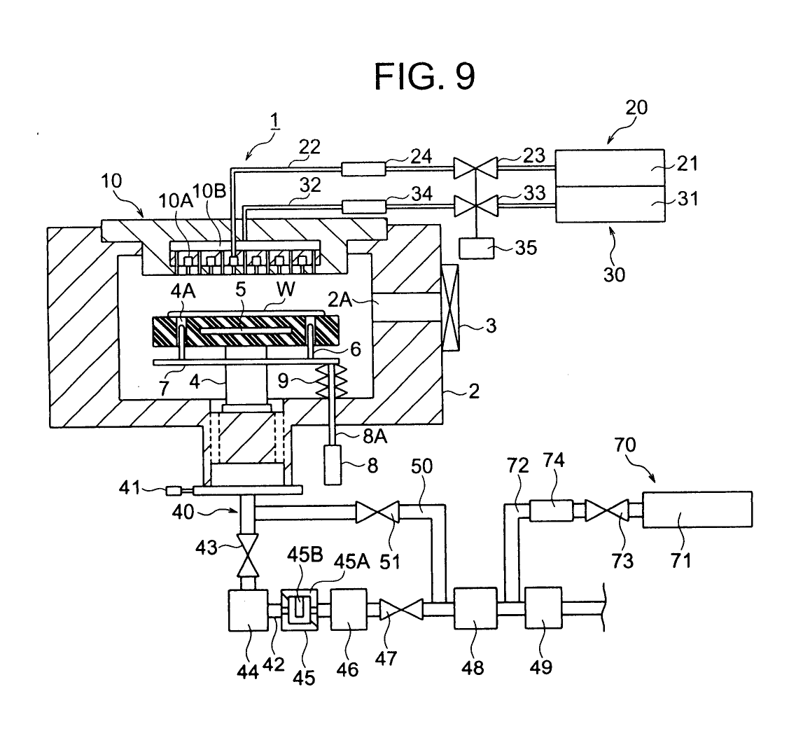

FIG. 9 is a schematic block diagram of a deposition device according to this embodiment. As shown in FIG. 9, an N₂ supply system 70 to supply N₂ into an exhaust pipe 42 is connected to the exhaust pipe 42 that is on a downstream side of a dry pump 48. The N₂ supply system 70 has an N₂ supply source 71 storing N₂ therein. An N₂ supply pipe 72 having one end connected to the exhaust pipe 42 that is on the downstream side of the dry pump 48 is connected to the N₂ supply source 71. A valve 73 and a mass flow controller 74 to control the flow rate of N₂ are disposed in the N₂ supply pipe 72. When the valve 73 is opened while the mass flow controller 74 is in a controlled state, N₂ is supplied into the exhaust pipe 42 from the N₂ supply source 71 at a predetermined flow rate.

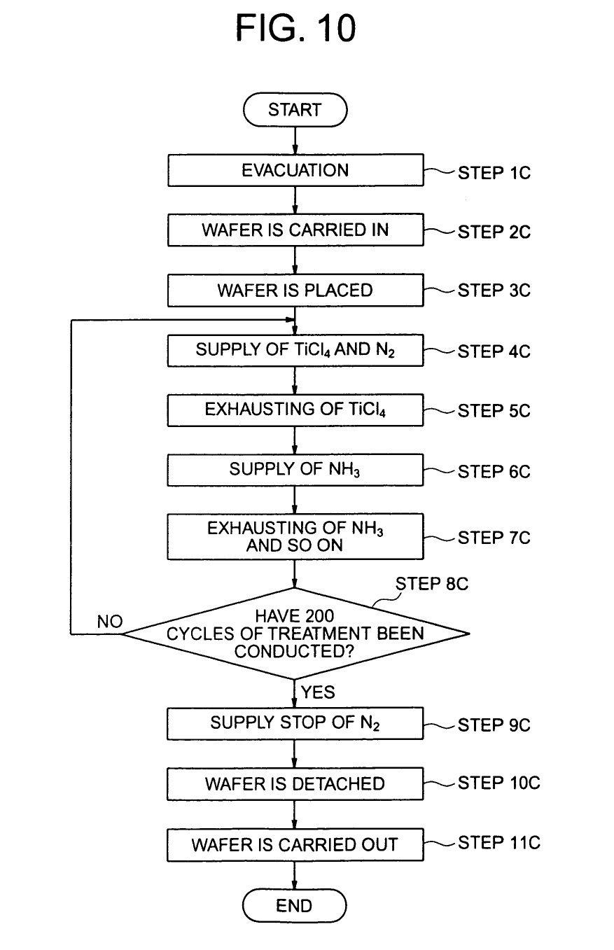

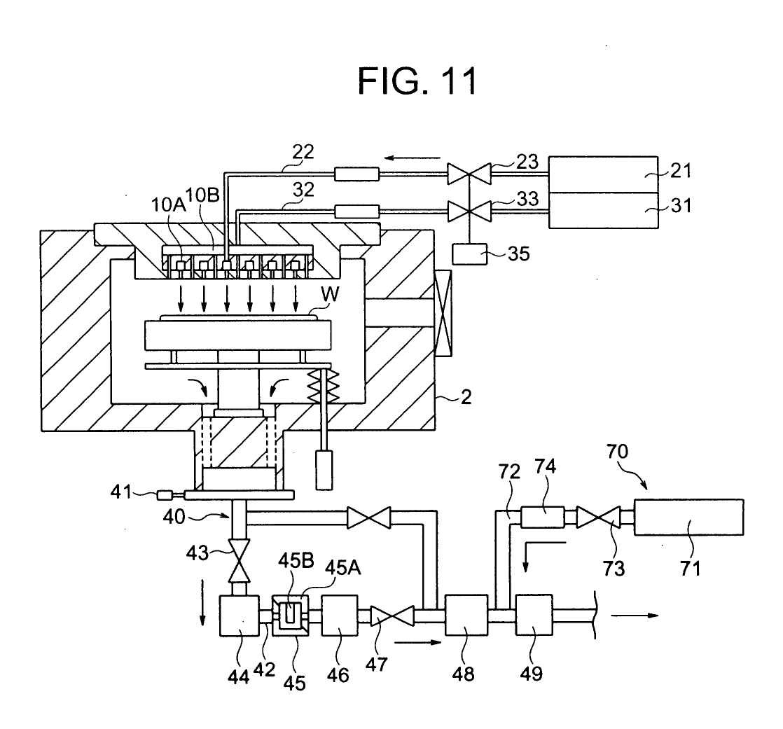

Hereinafter, the flow of the treatment conducted in a deposition device 1 will be explained, following FIG. 10 and FIG. 11. FIG. 10 is a flowchart showing the flow of the treatment conducted in the deposition device 1 according to this embodiment, and FIG. 11 is a view schematically showing the treatment conducted in the deposition device 1 according to this embodiment.

The dry pump 48 is operated to conduct low evacuation of the inside of a chamber 2. Thereafter, the low evacuation by the dry pump 48 is changed to high evacuation by a turbo molecular pump 44 (Step 1C).

After the pressure inside the chamber 2 is reduced to, for example, 1.33×10⁻² Pa or lower, a not-shown transfer arm holding a wafer W extends to carry the wafer W into the chamber 2 (Step 2C). Thereafter, wafer up/down pins 6 are moved down to place the wafer W on a susceptor 4 (Step 3C).

After the temperature of the wafer W is raised, a valve 23 is opened while the pressure inside the chamber 2 is kept at about 50 Pa to about 400 Pa, so that TiCl₄ is introduced from a TiCl₄ introducing portion 10A. At this time, N₂ is also supplied into the exhaust pipe 42 at a flow rate of about 1 L/min to about 50 L/min as shown in FIG. 11 (Step 4C). After a predetermined period of time passes, the valve 23 is closed to stop the supply of TiCl₄ and at the same time, TiCl₄ remaining in the chamber 2 is exhausted from the chamber 2 (Step 5C).

After a predetermined period of time passes, the valve 33 is opened, so that NH₃ is introduced from an NH₃ introducing portion 10B (Step 6C). After a predetermined period of time passes, the valve 33 is closed to stop the supply of NH₃ and at the same time, NH₃ and so on remaining in the chamber 2 are exhausted from the chamber 2 (Step 7C).

After a predetermined period of time passes, it is judged whether or not 200 cycles of the treatment have been conducted (Step 8C). When it is judged that 200 cycles of the treatment have not been conducted, the processes from Step 4C to Step 7C are conducted again.

When it is judged that 200 cycles of the treatment have been conducted, the valve 73 is closed to stop the supply of N₂ to the exhaust pipe 42 (Step 9C). Thereafter, the wafer up/down pins 6 are moved up, so that the wafer W is detached from the susceptor 4 (Step 10C). Finally, the wafer W is carried out of the chamber 2 by the not-shown transfer arm (Step 11C).

In this embodiment, since the N₂ supply system 70 to supply N₂ is disposed in the exhaust pipe 42 that is on the downstream side of the dry pump 48, the clogging of the exhaust pipe 42 can be reduced. To be more specific, the inside of the exhaust pipe 42 that is on the downstream side of the dry pump 48 is kept at the atmospheric pressure. Therefore, when N₂ is supplied into the exhaust pipe 42 that is on the downstream side of the dry pump 48, the pressure of TiCl₄ is lowered to reduce liquid TiCl₄. Further, the supply of N₂ causes TiCl₄ to be pushed out, so that TiCl₄ is not easily adsorbed by an inner wall of the exhaust pipe 42 and TiCl₄ adsorbed by the inner wall of the exhaust pipe 42 is easily detached. Consequently, yellow powder adhering to the inner wall of the exhaust pipe 42 can be greatly reduced to reduce the clogging of the exhaust pipe 42. As a result, maintenance frequency can be lowered.

(Fourth Embodiment)

Hereinafter, a fourth embodiment of the present invention will be explained. In this embodiment, the explanation will be given on an example where provided is a tape heater for heating an exhaust pipe that is on a downstream side of a dry pump.

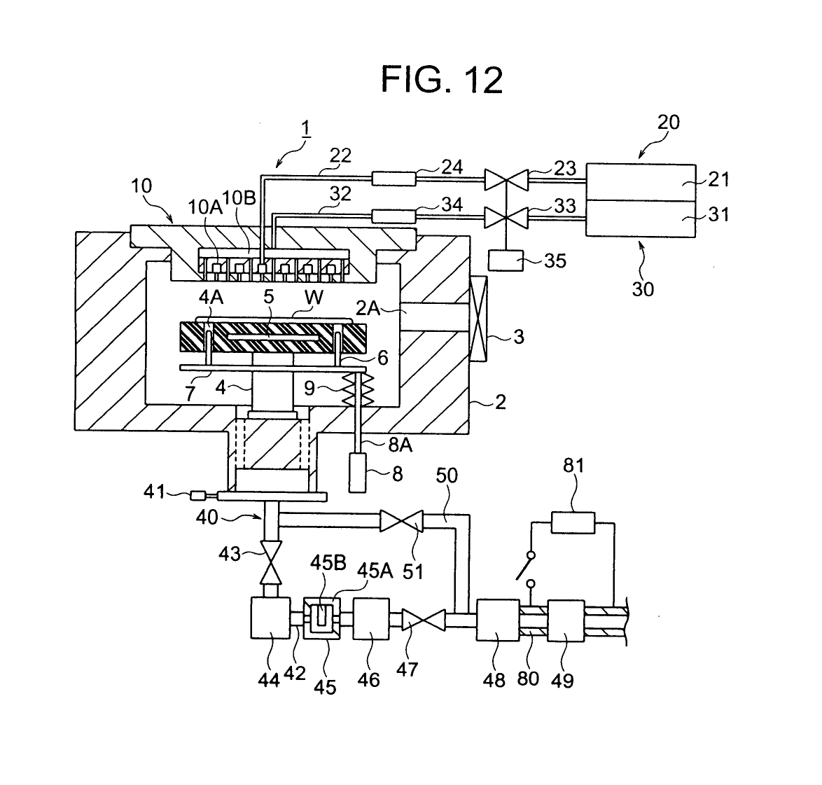

FIG. 12 is a schematic block diagram of a deposition device according to this embodiment. As shown in FIG. 12, a tape heater 80 for heating an exhaust pipe 42 is wound around an external wall of the exhaust pipe 42 that is on a downstream side of a dry pump 48. A tape heater controller 81 that controls the heating temperature of the tape heater 80 by adjusting an electric current passing through the tape heater 80 is electrically connected to the tape heater 80.

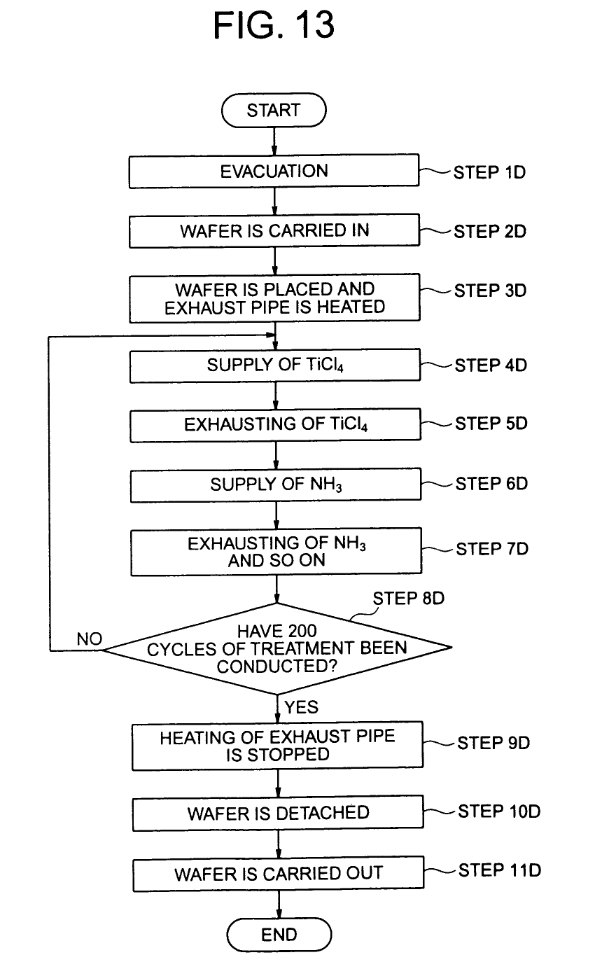

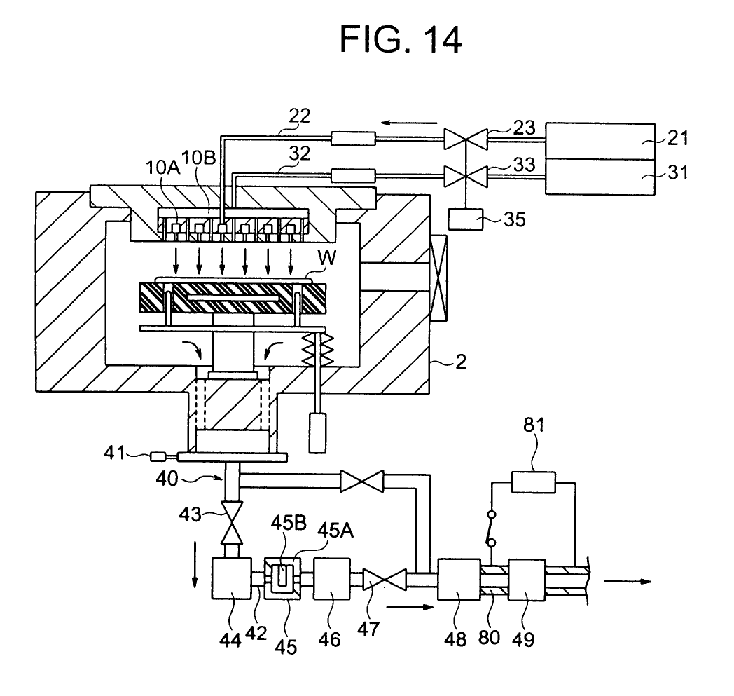

Hereinafter, the flow of the treatment conducted in a deposition device 1 will be explained, following FIG. 13 and FIG. 14. FIG. 13 is a flowchart showing the flow of the treatment conducted in the deposition device 1 according to this embodiment, and FIG. 14 is a view schematically showing the treatment conducted in the deposition device 1 according to this embodiment.

The dry pump 48 is operated to conduct low evacuation of the inside of a chamber 2. Thereafter, the low evacuation by the dry pump 48 is changed to high evacuation by a turbo molecular pump 44 (Step 1D).

After the pressure inside the chamber 2 is reduced to, for example, 1.33×10⁻² Pa or lower, a not-shown transfer arm holding a wafer W extends to carry the wafer W into the chamber 2 (Step 2D). Thereafter, wafer up/down pins 6 are moved down to place the wafer W on a susceptor 4. Further, the exhaust pipe 42 is heated by the tape heater 80 to about 60° C. to about 100° C. (Step 3D).

After the temperature of the wafer W is raised and the temperature of the exhaust pipe 42 becomes stable at 60° C. to 100° C., a valve 23 is opened while the pressure inside the chamber 2 is kept at about 50 Pa to about 400 Pa, so that TiCl₄ is introduced from a TiCl₄ introducing portion 10A as shown in FIG. 14 (Step 4D). After a predetermined period of time passes, the valve 23 is closed to stop the supply of TiCl₄ and at the same time, TiCl₄ remaining in the chamber 2 is exhausted from the chamber 2 (Step 5D).

After a predetermined period of time passes, a valve 33 is opened, so that NH₃ is introduced from an NH₃ introducing portion 10B (Step 6D). After a predetermined period of time passes, the valve 33 is closed to stop the supply of NH₃ and at the same time, NH₃ and so on remaining in the chamber 2 are exhausted from the chamber 2 (Step 7D).

After a predetermined period of time passes, it is judged whether or not 200 cycles of the treatment have been conducted (Step 8D). When it is judged that 200 cycles of the treatment have not been conducted, the processes from Step 4D to Step 7D are conducted again.

When it is judged that 200 cycles of the treatment have been conducted, the heating of the exhaust pipe 42 by the tape heater 80 is stopped (Step 9D). Thereafter, the wafer up/down pins 6 are moved up, so that the wafer W is detached from the susceptor 4 (Step 10D). Finally, the wafer W is carried out of the chamber 2 by the not-shown transfer arm (Step 11D).

In this embodiment, since the tape heater 80 for heating the exhaust pipe 42 that is on the downstream side of the dry pump 48 is provided, the clogging of the exhaust pipe 42 can be reduced. To be more specific, when the exhaust pipe 42 that is on the downstream side of the dry pump 48 is heated, TiCl₄ is not easily liquefied and liquid TiCl₄ is liable to turn into gas again. Accordingly, liquid TiCl₄ is reduced. Further, when the exhaust pipe 42 that is on the downstream side of the dry pump 48 is heated, TiCl₄ adsorbed by an inner wall of the exhaust pipe 42 is easily detached from the inner wall of the exhaust pipe 42. Consequently, an amount of TiCl₄ adhering to the inner wall of the exhaust pipe 42 is reduced. This makes it possible to greatly reduce yellow powder adhering to the inner wall of the exhaust pipe 42 to reduce the clogging of the exhaust pipe 42. As a result, maintenance frequency can be lowered.

(Fifth Embodiment)

Hereinafter, a fifth embodiment of the present invention will be explained. In this embodiment, the explanation will be given on an example where NH₃ is supplied at a flow rate about 10 times as large as the flow rate of TiCl₄ or at a larger flow rate.

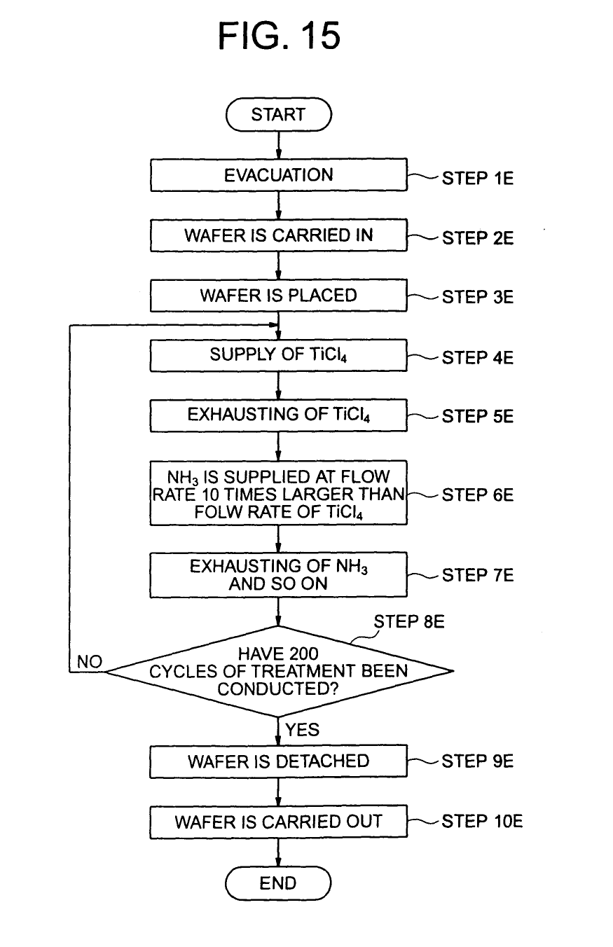

FIG. 15 is a flow chart showing the flow of the treatment conducted in a deposition device 1 according to this embodiment. Note that the deposition device of this embodiment is a similar one to the deposition device in the first embodiment, but the capturing unit 46 is not disposed.

A dry pump 48 is operated to conduct low evacuation of the inside of a chamber 2. Thereafter, the low evacuation by the dry pump 48 is changed to high evacuation by a turbo molecular pump 44 (Step 1E).

After the pressure inside the chamber 2 is reduced to, for example, 1.33×10⁻² Pa or lower, a not-shown transfer arm holding a wafer W extends to carry the wafer W into the chamber 2 (Step 2E). Thereafter, wafer up/down pins 6 are moved down to place the wafer W on a susceptor 4 (Step 3E).

After the temperature of the wafer W is raised, a valve 23 is opened while the pressure inside the chamber 2 is kept at about 50 Pa to about 400 Pa, so that TiCl₄ is introduced from a TiCl₄ introducing portion 10A at a flow rate of about 30 sccm (Step 4E). After a predetermined period of time passes, the valve 23 is closed to stop the supply of TiCl₄ and at the same time, TiCl₄ remaining in the chamber 2 is exhausted from the chamber 2 (Step 5E).

After a predetermined period of time passes, a valve 33 is opened, so that NH₃ is introduced from an NH₃ introducing portion 10B at a flow rate of about 300 sccm to about 1000 sccm (Step 6E). After a predetermined period of time passes, the valve 33 is closed to stop the supply of NH₃ and at the same time, NH₃ and so on remaining in the chamber 2 are exhausted from the chamber 2 (Step 7E).

After a predetermined period of time passes, it is judged whether or not 200 cycles of the treatment have been conducted (Step 8E). When it is judged that 200 cycles of the treatment have not been conducted, the processes from Step 4E to Step 7E are conducted again.

When it is judged that 200 cycles of the treatment have been conducted, the wafer up/down pins 6 are moved up, so that the wafer W is detached from the susceptor 4 (Step 9E). Finally, the wafer W is carried out of the chamber 2 by the not-shown transfer arm (Step 10E).

In this embodiment, since NH₃ is supplied at a flow rate about 10 times as large as the flow rate of TiCl₄ or at a larger rate, the clogging of an exhaust pipe 42 can be reduced. As a result, maintenance frequency can be lowered.

### EXAMPLE

Hereinafter, an example will be explained. In this example, the deposition device according to the fifth embodiment was used and the degree of the clogging of the exhaust pipe was observed.

Measurement conditions will be explained. In this example, a TiN film was formed on a wafer, using the deposition device according to the fifth embodiment. Incidentally, the TiN film with a thickness of about 10 nm was formed on each of the wafers. TiCl₄ was supplied at a flow rate of about 30 sccm and NH₃ was supplied at a flow rate of about 800 sccm. Further, for comparison with this example, TiCl₄ was supplied at a flow rate of about 30 sccm and NH₃ was supplied at a flow rate of about 100 sccm, and the degree of the clogging of the exhaust pipe 42 in this case was also observed.

The measurement results will be discussed. When TiCl₄ was supplied at a flow rate of about 30 sccm and NH₃ was supplied at a flow rate of about 100 sccm, the exhaust pipe was clogged at the time after the TiN film was formed on 30 pieces of the wafer and maintenance was required. On the other hand, when TiCl₄ was supplied at a flow rate of about 30 sccm and NH₃ was supplied at a flow rate of about 800 sccm, even the TiN film formation on 100 pieces of the wafers did not cause the exhaust pipe to be clogged, and maintenance was not required. It has been confirmed from these results that the supply of NH₃ at a flow rate about 10 times as large as the flow rate of TiCl₄ or at a larger rate reduces the clogging of the exhaust pipe to lower maintenance frequency.

(Sixth Embodiment)

Hereinafter, a sixth embodiment of the present invention will be explained. In this embodiment, the explanation will be given on an example where NH₃ is periodically supplied into an exhaust pipe while a deposition device does not have a wafer carried therein.

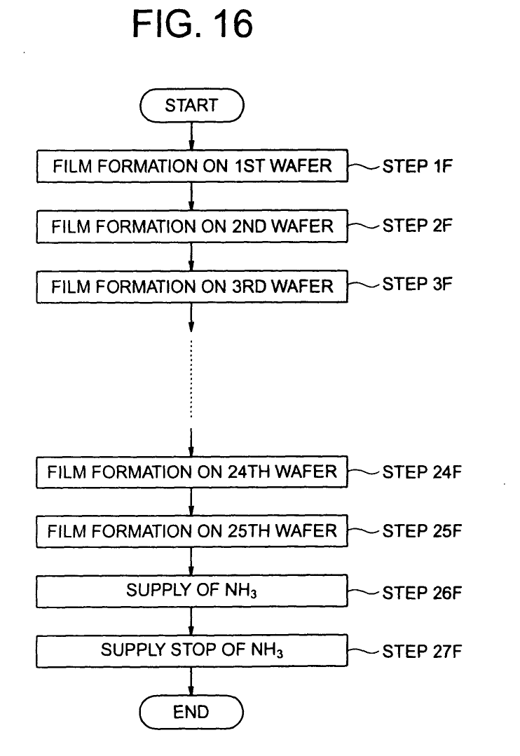

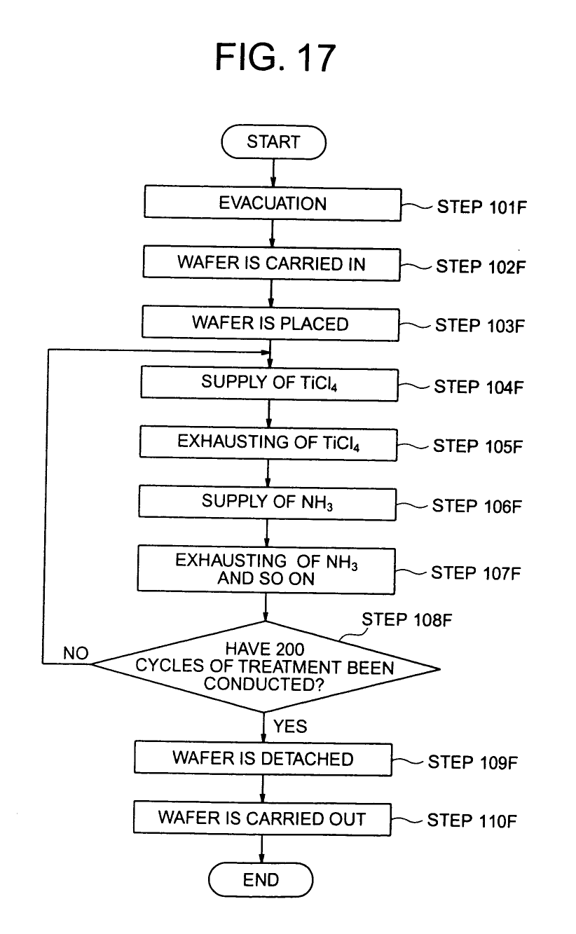

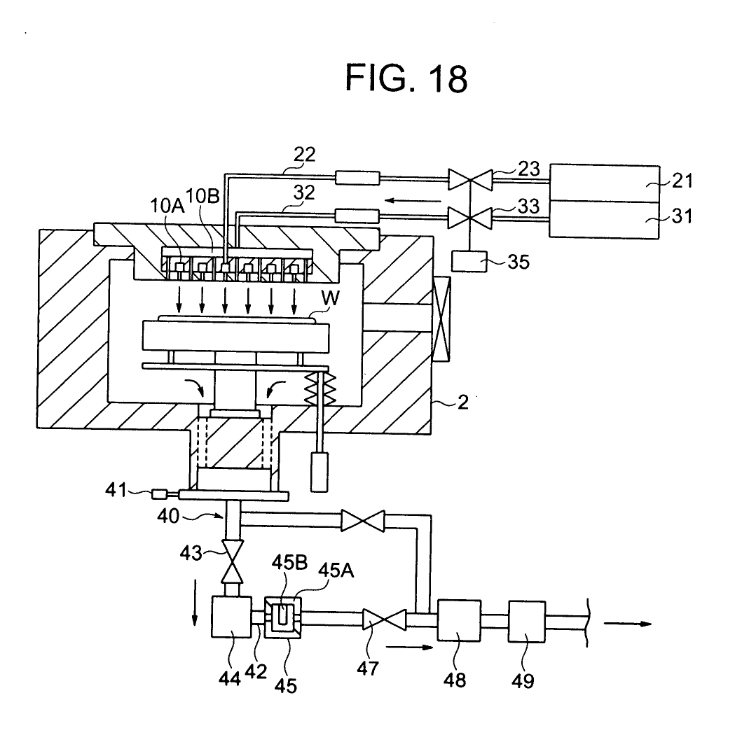

FIG. 16 is a flowchart showing the flow of the overall treatment conducted in the deposition device according to this embodiment, FIG. 17 is a flowchart showing the flow of the treatment for one piece of wafer conducted in the deposition device according to this embodiment, and FIG. 18 is a view schematically showing the treatment conducted in the deposition device according to this embodiment. The deposition device of this embodiment is a similar one to the deposition device of the first embodiment, but the capturing unit 46 is not disposed.

First, a TiN film is formed on the first wafer W (Step 1F). Concretely, high evacuation is first conducted by a turbo molecular pump 44 (Step 101F). After the pressure inside a chamber 2 is reduced to, for example, 1.33×10⁻² Pa or lower, the first wafer W is carried into the chamber 2 and placed on a susceptor 4 thereafter (Step 102F, Step 103F). After the temperature of the wafer W is raised, TiCl₄ is introduced from a TiCl₄ introduceing portion 10A at a flow rate of about 30 sccm (Step 104F). Thereafter, the supply of TiCl₄ is stopped, and at the same time, TiCl₄ remaining in the chamber 2 is exhausted from the chamber 2 (Step 105F). After a predetermined period of time passes, NH₃ is introduced at a flow rate of about 100 sccm (Step 106F). Thereafter, the supply of NH₃ is stopped, and at the same time, NH₃ and so on remaining in the chamber 2 are exhausted from the chamber 2 (Step 107F). After a predetermined period of time passes, it is judged whether or not 200 cycles of the treatment have been conducted (Step 108F). When it is judged that 200 cycles of the treatment have not been conducted, the processes from Step 104F to Step 107F are conducted again. When it is judged that 200 cycles of the treatment have been conducted, the wafer W is detached from the susceptor 4, and the first wafer W is carried out of the chamber 2 by a not-shown transfer arm (Step 109F, Step 110F).

Subsequently, the same processes as in Step 101F to Step 110F are also conducted for the second, third, . . . , twenty-fifth wafers W respectively (Step 2F to Step 25F).

After the twenty-fifth wafer W is carried out of the chamber 2, a valve 33 is opened while the turbo molecular pump 44 and a dry pump 48 are in operation, so that NH₃ is introduced from an NH₃ introducing portion 10B at a flow rate of about 300 sccm to about 1000 sccm, as shown in FIG. 18 (Step 26F). The introduced NH₃ is supplied into an exhaust pipe 42 that is on a downstream side of the dry pump 48 via the chamber 2. The supply of NH₃ while the deposition device 1 does not have the wafer W carried therein is conducted periodically. Specifically, it is conducted for, for example, every 1 lot (25 pieces of the wafers). After a predetermined period of time passes, the valve 33 is closed to stop the supply of NH₃ (Step 27F).

In this embodiment, since NH₃ is supplied into the exhaust pipe 42 while the deposition device 1 does not have the wafer W carried therein, the clogging of the exhaust pipe 42 can be reduced. Therefore, the frequency for removing yellow powder by opening the exhaust pipe 42 can be lowered.

It should be noted that the present invention is not limited to the descried contents in the above embodiments, and the structure, the materials, the arrangement of each member, and so on are appropriately changeable within a range not departing from the sprit of the present invention. Table 1 presents examples of treatment gases for forming film species and these films. TiCl₄ and NH₃ are used in the first embodiment and the third to sixth embodiments, and TiCl₄, SiH₂Cl₂, and NH₃ are used in the second embodiment, but the treatment gases shown in Table 1 are also usable.

TABLE 1

| | First | Second | Third | | First | Second | Third |
|---|---|---|---|---|---|---|---|
| Film | Treatment | Treatment | Treatment | Film | Treatment | Treatment | Treatment |
| Species | Gas | Gas | Gas | Species | Gas | Gas | Gas |
| TiN | TiCl₄ | NH₃ | — | TaN | TaF₅ | NH₃ | — |
| | TiF₄ | NH₃ | — | | TaCl₅ | NH₃ | — |
| | TiBr₄ | NH₃ | — | | TaBr₅ | NH₃ | — |
| | TiI₄ | NH₃ | — | | TaI₅ | NH₃ | — |
| | TEMAT | NH₃ | — | | TBTDET | NH₃ | — |
| | TDMAT | NH₃ | — | TaSiN | TaF₅ | NH₃ | SiH₄ |
| | TDEAT | NH₃ | — | | TaCl₅ | NH₃ | SiH₄ |
| TiSiN | TiCl₄ | NH₃ | SiH₄ | | TaBr₅ | NH₃ | SiH₄ |
| | TiF₄ | NH₃ | SiH₄ | | TaI₅ | NH₃ | SiH₄ |
| | TiBr₄ | NH₃ | SiH₄ | | TBTDET | NH₃ | SiH₄ |
| | TiI₄ | NH₃ | SiH₄ | | TaF₅ | NH₃ | Si₂H₆ |
| | TEMAT | NH₃ | SiH₄ | | TaCl₅ | NH₃ | Si₂H₆ |
| | TDMAT | NH₃ | SiH₄ | | TaBr₅ | NH₃ | Si₂H₆ |
| | TDEAT | NH₃ | SiH₄ | | TaI₅ | NH₃ | Si₂H₆ |
| | TiCl₄ | NH₃ | Si₂H₆ | | TBTDET | NH₃ | Si₂H₆ |
| | TiF4 | NH₃ | Si₂H₆ | | TaF₅ | NH₃ | SiH₂Cl₂ |
| | TiBr₄ | NH₃ | Si₂H6 | | TaCl₅ | NH₃ | SiH₂Cl₂ |
| | TiI₄ | NH₃ | Si₂H₆ | | TaBr₅ | NH₃ | SiH₂Cl₂ |
| | TEMAT | NH₃ | Si₂H₆ | | TaI₅ | NH₃ | SiH₂Cl₂ |
| | TDMAT | NH₃ | Si₂H₆ | | TBTDET | NH₃ | SiH₂Cl₂ |
| | TDEAT | NH₃ | Si₂H₆ | | TaF₅ | NH₃ | SiCl₄ |
| | TiCl₄ | NH₃ | SiH₂Cl₂ | | TaCl₅ | NH₃ | SiCl₄ |
| | TiF₄ | NH₃ | SiH₂Cl₂ | | TaBr₅ | NH₃ | SiCl₄ |
| | TiBr₄ | NH₃ | SiH₂Cl₂ | | TaI₅ | NH₃ | SiCl₄ |
| | TiI₄ | NH₃ | SiH₂Cl₂ | | TBTDET | NH₃ | SiCl₄ |
| | TEMAT | NH₃ | SiH₂Cl₂ | Al₂O₃ | Al(CH₃)₃ | H₂O | — |
| | TDMAT | NH₃ | SiH₂Cl₂ | | Al(CH₃)₃ | H₂O₂ | — |
| | TDEAT | NH₃ | SiH₂Cl₂ | ZrO₂ | Zr(O-t(C₄H₉))₄ | H₂O | — |
| | TiCl₄ | NH₃ | SiCl₄ | | Zr(O-t(C₄H₉))₄ | H₂O₂ | — |
| | TiF₄ | NH₃ | SiCl₄ | | ZrCl₄ | H₂O | — |
| | TiBr₄ | NH₃ | SiCl₄ | | ZrCl₄ | H₂O₂ | — |
| | TiI₄ | NH₃ | SiCl₄ | Ta₂O₅ | Ta(OC₂H₅)₅ | O₂ | — |
| | TEMAT | NH₃ | SiCl₄ | | Ta(OC₂H₅)₅ | H₂O | — |
| | TDMAT | NH₃ | SiCl₄ | | Ta(OC₂H₅)₅ | H₂O₂ | — |
| | TDEAT | NH₃ | SiCl₄ | | | | |

TiCl₄ and NH₃ are supplied in the order of TiCl₄ and NH₃ in the first embodiment and the third to sixth embodiments described above, and TiCl₄, SiH₂Cl₂, and NH₃ are supplied in the order of TiCl₄, SiH₂Cl₂, and NH₃ in the second embodiment, but the supply order is not limited to these orders. The same applies to the treatment gases shown in the aforesaid Table 1.

The capturing unit 46 is disposed in the third embodiment, but the structure in which the capturing unit 46 is not disposed may also be adopted. The tape heater 80 may be wound around as in the fourth embodiment. Further, N₂ is supplied into the exhaust pipe 42, but other inert gas may be supplied. Moreover, though N₂ is supplied into the exhaust pipe 42 at the time of the supply of TiCl₄, it is also possible to start supplying N₂ into the exhaust pipe 42 before the supply of TiCl₄.

In the fourth embodiment, the exhaust pipe 42 is heated to 60° C. to 100° C., but the heating temperature is not limited to a specific value as long as it is the temperature causing the evaporation of the metal-containing gas. For example, when the metal-containing gas is TaF₅ or TaCl₅ the exhaust pipe 42 is heated to 80° C. to 200° C. When the metal-containing gas is Al(CH₃)₃, Zr(O-t(C₄H₉₎₎₄, or Ta(OC₂H₅)₅, the exhaust pipe 42 is heated to 80° C. to 150° C. Further, the exhaust pipe 42 is heated after the wafer W is carried in, but it is also possible to start heating the exhaust pipe 42 before the wafer W is carried in or while the wafer W is being carried in.

In the fourth embodiment, the capturing unit 46 is disposed, but the structure without the capturing unit 46 may also be adopted. The tape heater 80 is wound around the exhaust pipe 42, but any other type is usable as long as it can heat the exhaust pipe 42.

In the fifth and sixth embodiments, any of the capturing unit 46, the N₂ supply system 70, and the tape heater 80 is not disposed, but it is also possible to dispose at least one of these components. In these cases, a larger amount of TiCl₄ can be captured.

In the first to sixth embodiments, the wafer W is used, but a glass substrate may be used. Further, the explanation is given on the deposition device 1 that forms a film by alternately supplying TiCl₄ and NH₃ or by supplying TiCl₄, SiH₂Cl₂, and NH₃ by turns, but the present invention is also applicable to a deposition device that forms a film by supplying these gases simultaneously.

In the first to sixth embodiments, the chamber 2 is evacuated to exhaust TiCl₄ and so on, but it is also possible to supply a purge gas such as N₂ into the chamber 2 at the time of the evacuation. It is also possible to repeat the supply of the purge gas and vacuuming. Moreover, the present invention is applicable to an etching apparatus, not limited to the deposition device. In this case, at least two kinds of etching gases may be alternately supplied or simultaneously supplied.

What is claimed is:

1. A substrate treatment device comprising:
a treatment chamber in which a substrate is to be placed;
a supply system configured to supply at least two kinds of treatment gases to said treatment chamber;
an exhaust system having a pump, configured to exhaust the treatment gases from said treatment chamber; and
a capturing unit interposed between said treatment chamber and said pump and containing fine grains, configured to capture by the fine grains at least one kind of the treatment gas exhausted from said treatment chamber.

2. A substrate treatment device as set forth in claim 1, wherein the fine grains contained in said capturing unit are zeolite.

3. A substrate treatment device as set forth in claim 1, wherein said capturing unit captures the treatment gas that is liquid or solid at room temperature and at atmospheric pressure

4. A substrate treatment device as set forth in claim 1, wherein the treatment gas captured by said capturing unit is at least one of TiF₄, TiCl₄, TiBr₄, TiI₄, Ti[N(C₂H₅CH₃)₂]₄, Ti[N(CH₃)₂]₄, Ti[N(C₂H₅)₂]₄, TaF₅, TaCl₅, TaBr₅, TaI₅, Ta(NC(CH₃)₃)(N(C₂H₅)₂)₃, Ta(OC₂H₅)₅, Al(CH₃)₃, Zr(O-t(C₄H₉))₄, ZrCl₄, SiH₄, Si₂H₆, SiH₂Cl₂, and SiCl₄.

5. A substrate treatment device as set forth in claim 1, further comprising:
a supply controller configured to control said supply system to supply the treatment gases alternately.

6. A substrate treatment device comprising:
a treatment chamber in which a substrate is to be placed;
a supply system configured to supply at least two kinds of treatment gases to said treatment chamber;
an exhaust system having a pump, configured to exhaust the treatment gases from said treatment chamber; and
a capturing unit interposed between said treatment chamber and said pump, configured to capture by a chemical action at least one kind of the treatment gas exhausted from said treatment chamber.

7. A substrate treatment device as set forth in claim 6, wherein said capturing unit has a metal oxide to capture the treatment gas.

8. A substrate treatment device as set forth in claim 7, wherein the metal oxide is Al₂O₃.

9. A substrate treatment device as set forth in claim 6, further comprising:
a supply controller configured to control said supply system to alternately supply the treatment gases.

10. A substrate treatment device comprising:
a treatment chamber in which a substrate is to be placed;
a supply system configured to supply at least two kinds of treatment gases to said treatment chamber;
an exhaust system having at least one pump, configured to exhaust the treatment gases from said treatment chamber; and
an inert gas supply system configured to supply an inert gas into said exhaust system that is on a downstream side of the pump on a final stage.

11. A substrate treatment device as set forth in claim 10, wherein the inert gas includes at least one of Ar, He, and N₂.

12. A substrate treatment device as set forth in claim 10, wherein the treatment gases include at least one of TiF₄, TiCl₄, TiBr₄, TiI₄, Ti[N(C₂H₅CH₃)₂]₄, Ti[N(CH₃)₂]₄, Ti[N(C₂H₅)₂]₄, TaF₅, TaCl₅, TaBr₅, TaI₅, Ta(NC(CH₃)₃)(N(C₂H₅)₂)₃, Ta(OC₂H₅)₅, Al(CH₃)₃, Zr(O-t(C₄H₉))₄, ZrCl₄, SiH₄, Si₂H₆, SiH₂Cl₂, and SiCl₄.

13. A substrate treatment device as set forth in claim 10, further comprising:
a supply controller configured to control said supply system to alternately supply the treatment gases.

14. A substrate treatment device comprising:
a treatment chamber in which a substrate is to be placed;
a supply system configured to supply at least two kinds of treatment gases into said treatment chamber;
an exhaust system having at least one pump, configured to exhaust the treatment gases from said treatment chamber;
a heater configured to heat said exhaust system that is on a downstream side of the pump on a final stage.

15. A substrate treatment device as set forth in claim 14, wherein the treatment gases include at least one of TiF₄, TiCl₄, TiBr₄, TiI₄, Ti[N(C₂H₅CH₃)₂]₄, Ti[N(CH₃)₂]₄, Ti[N(C₂H₅)₂]₄, TaF₅, TaCl₅, TaBr₅, TaI₅, Ta(NC(CH₃)₃)(N(C₂H₅)₂)₃, Ta(OC₂H₅)₅, Al(CH₃)₃, Zr(O-t(C₄H₉))₄, ZrCl₄, SiH₄, Si₂H₆, SiH₂Cl₂, and SiCl₄.

16. A substrate treatment device as set forth in claim 14, further comprising:
a supply controller configured to control said supply system to supply said treatment gases alternately.

17. A substrate treatment method comprising:
a metal-containing gas supply step of supplying a metal-containing gas at a first flow rate into a treatment chamber while the treatment chamber has a substrate placed therein;
a metal-containing gas exhaust step of exhausting the metal-containing gas from the treatment chamber via an exhaust system;
a nitriding agent gas supply step of supplying a nitriding agent gas into the treatment chamber at a second flow rate that is 10 times as large as the first flow rate or at a larger rate; and
a nitriding agent exhaust step of exhausting the nitriding agent gas from the treatment chamber via the exhaust system.

18. A substrate treatment method as set forth in claim 17, wherein the nitriding agent gas is supplied at a flow rate of 300 sccm to 1000 sccm.

19. A substrate treatment method as set forth in claim 17, wherein the metal-containing gas includes at least one of TiF₄, TiCl₄, TiBr₄, TiI₄, Ti[N(C₂H₅CH₃)₂]₄, Ti[N(CH₃)₂]₄, Ti[N(C₂H₅)₂]₄, TaF₅, TaCl₅, TaBr₅, TaI₅, and Ta(NC(CH₃)₃)(N(C₂H₅)₂)₃.

20. A substrate treatment method as set forth in claim 17, wherein the nitriding agent gas includes NH₃.

21. A cleaning method for a substrate treatment device, comprising:
a substrate treatment device preparing step of preparing a substrate treatment device that treats a substrate by supplying a metal-containing gas and a nitriding agent gas to the substrate; and
a nitriding agent gas supply step of supplying a nitriding agent gas into an exhaust system of the substrate treatment device while the substrate treatment device does not have the substrate placed therein.

22. A cleaning method for a substrate treatment device as set forth in claim 21, wherein the nitriding agent gas supplied in said nitriding agent gas supply step is supplied at a flow rate larger than a flow rate of the nitriding agent gas supplied for the treatment.

23. A cleaning method for a substrate treatment device as set forth in claim 21, wherein the nitriding agent gas supplied in said nitriding agent gas supply step is supplied at a flow rate of 300 sccm to 1000 sccm.

24. A cleaning method for a substrate treatment device as set forth in claim 21, wherein the metal-containing gas includes at least one of TiF₄, TiCl₄, TiBr₄, TiI₄, Ti[N(C₂H₅CH₃)₂]₄, Ti[N(CH₃)₂]₄, Ti[N(C₂H₅)₂]₄, TaF₅, TaCl₅, TaBr₅, TaI₅, and Ta(NC(CH₃)₃)(N(C₂H₅)₂)₃.

25. A cleaning method for a substrate treatment device as set forth in claim 21, wherein the nitriding agent gas includes NH₃.

26. A cleaning method for a substrate treatment device, comprising
a nitriding agent gas supply step of supplying a nitriding agent gas into an exhaust system of the substrate treatment device that treats a substrate by supplying a metal-containing gas and a nitriding agent gas, while the substrate treatment device does not have the substrate placed therein.
